(19) United States
(12) Patent Application Publication
(10) Pub. No.: US 2003/0223210 A1
(43) Pub. Date: Dec. 4, 2003

(54) Modular LED circuit board

(76) Inventor: Yoon Chin, Toronto (CA)

Correspondence Address: ELIAS C. BORGES, 1 EVA ROAD, SUITE 406, TORONTO, ON, M9C 4Z5, CA

(21) Appl. No.: 10/171,488

(22) Filed: Jun. 3, 2002

(51) Int. Cl. G11C 11/00

(52) U.S. Cl. 361/806

(57) ABSTRACT

A modular LED circuit board consisting of a circuit board being frangible along a first and second set of intersecting fragmentation lines, the fragmentation lines dividing the circuit board into a plurality of sections. A plurality of LEDs are mounted to the circuit board, at least one LED being mounted to each section, each section having a sub-circuit operatively coupled to the LED, each sub-circuit having a positive and negative lead. The sub-circuits of adjacent sections are operatively coupled together by frangible leads.

### FIELD OF THE INVENTION

The invention relates generally to modular LED circuit boards for use in constructing LED signs and displays and general illumination.

### BACKGROUND OF THE INVENTION

LED displays are finding application in a variety of products. Display signs, advertising signs and lighting fixtures are a few examples. A majority of these LED displays use a plurality of LEDs mounted on a circuit board. For a majority of applications, each LED display requires a custom LED circuit board. As can be appreciated, the costs of manufacturing custom circuit boards can be quite high. To overcome the high cost of manufacturing custom LED boards, one approach has been to build LED displays from a plurality of modular LED boards. This approach does reduce the cost of manufacturing a LED display; however, this still requires the step of assembling a plurality of smaller LED boards to form a display. In some cases, the cost of assembling a suitable frame to mount the smaller LED boards may be as great as manufacturing a custom board. A modular LED board which is more versatile is therefore required.

### SUMMARY OF THE INVENTION

In accordance with the present invention, there is provided a modular LED circuit board consisting of a circuit board being frangible along a first and second set of intersecting fragmentation lines, the fragmentation lines dividing the circuit board into a plurality of sections. A plurality of LEDs are mounted to the circuit board, at least one LED being mounted to each section, each section having a sub-circuit operatively coupled to the LED, each sub-circuit having a positive and negative lead.

With the foregoing in view, and other advantages as will become apparent to those skilled in the art to which this invention relates as this specification proceeds, the invention is herein described by reference to the accompanying drawings forming a part hereof, which includes a description of the preferred typical embodiment of the principles of the present invention.

### DESCRIPTION OF THE DRAWINGS

FIG. 1. is a perspective view of a circuit board made in accordance with the invention.

FIG. 2. is a perspective view of the circuit board shown in FIG. 1 which has been fragmented into several fragments in accordance with the invention.

FIG. 3. is a top view of a circuit board made in accordance with the invention.

FIG. 4. is a top view of a fragment of the circuit board shown in FIG. 3.

FIG. 5. is a top view of a section of the fragment shown in FIG. 4 showing the sub-circuit.

FIG. 6. is a side view of the section shown in FIG. 5.

FIG. 7. is a schematic view of the circuit of the circuit board shown in FIG. 3.

In the drawings like characters of reference indicate corresponding parts in the different figures.

### DETAILED DESCRIPTION OF THE INVENTION

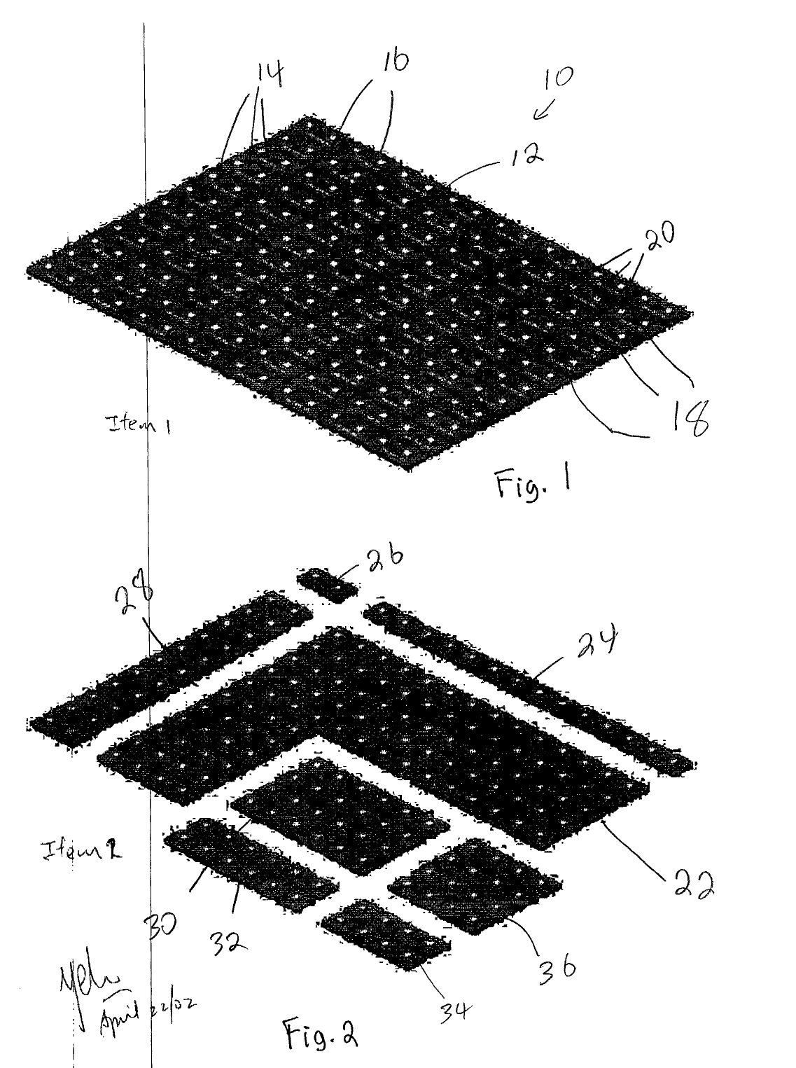

Referring firstly to FIGS. 1 and 2, the present invention is a modular LED circuit board, shown generally as item 10 which consists of a circuit board 12 which is frangible along intersecting fragmentation lines 14 and 16. Fragmentation lines 14 and 16 divide circuit board 12 into a plurality of modules 18. Each module 18 has LED's 20 mounted thereto. Preferably, circuit board 12 comprises a standard pre-printed circuit board. Fragmentation lines 14 and 16 may be either deep score lines or perforation lines.

Preferably, fragmentation lines 14 and 16 are arranged at right angles to each other such that modules 18 are rectangular. By arranging fragmentation lines 14 and 16 in a grid, board 12 may be broken into smaller fragments of various sizes and shapes. In the example illustrated in FIG. 2, board 12 has been broken into fragments 22, 24, 26, 28, 30, 32, 34 and 36 by breaking the board along the fragmentation lines. The smallest of these fragments, 26, is only the size of one module 18. Each of these fragments will have at least one LED mounted thereon.

While the particular arrangement of fragmentation lines illustrated in the drawings results in rectangular modules, it will be appreciated that any pattern of intersecting fragmentation lines may be used depending on the desired shape of the resulting modules. By selecting an appropriate pattern of intersecting fragmentation lines, square and even triangular modules may be created.

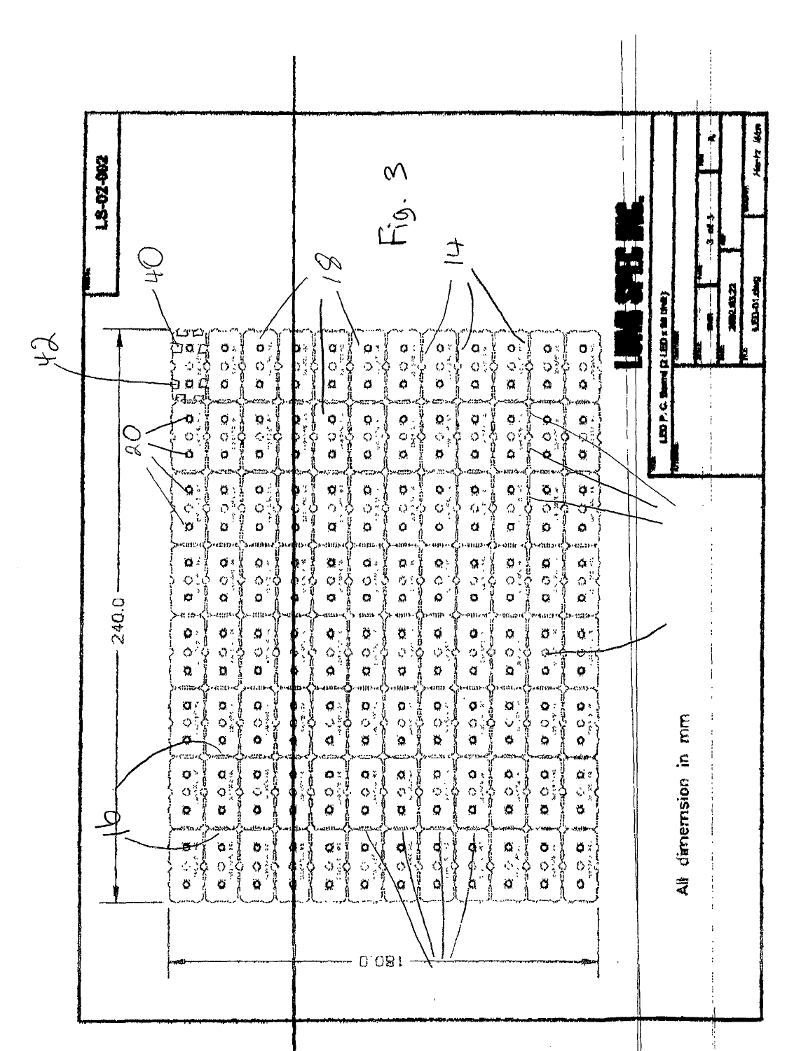

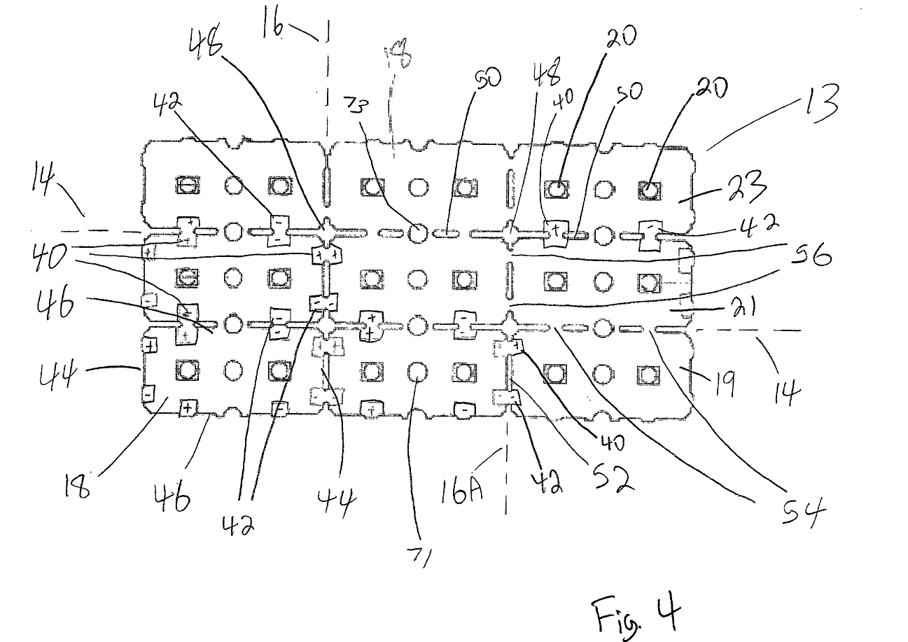

Referring now to FIG. 3, each module 18 has two LED's 20 mounted thereon. Any suitable LED or LED die may be used, however, surface mount LEDs are particularly useful. Each module 18 has a sub-circuit (see FIG. 5) operatively coupled to LED's 20. The sub-circuit has positive leads 40 and negative leads 42. Supplying a suitable electric current to leads 40 and 42 will cause LED's 20 to glow. Leads 40 and 42 of adjacent modules 18 are operatively coupled to each other such that when a suitable electric current is supplied to any pair of leads 40 and 42, all of the LED's on board 12 will glow.

Referring now to FIG. 4, a board fragment 13 is shown having a plurality of rectangular module 18. Each section 18 is rectangular and has opposite ends 44 and opposite sides 46 formed by fragmentation lines 16 and 14, respectively. The corners of sections 18 are formed from cross shaped apertures 48. Fragmentation lines 14 are basically perforated lines formed of apertures 50 and apertures 48. Likewise, fragmentation lines 16 are formed from apertures 52 and apertures 48. Adjacent sections 18 are connected together along opposite sides 46 by bridges 54. Likewise, adjacent modules 18 are connected together along opposite ends 44 by bridges 56. Each module 18 is provided with at least one positive lead 40 positioned at each end 44 and each side 46. Likewise, each module 18 is provided with at least one negative lead 42 positioned at each end 44 and each side 46. Hence, each module 18 will have four positive and four negative terminals. Providing four positive and negative terminals on each module greatly increases the flexibility of each module, since it can be supplied with electrical power from any side or end.

Leads 40 and 42 extend across bridges 54 and 56 such that the leads of adjacent modules 18 are electrically coupled to each other. Hence, suppling any positive and negative lead on board fragment 13 with an appropriate current will cause all of the LED's on the fragment to light. Board fragment 13 can be broken into still smaller fragments by breaking the board along one or more fragmentation lines. When fragment 13 is broken along a fragmentation line, the bridges linking adjacent rectangular modules 18 are broken, and the leads which cross those bridges are separated. For example, if sections 19, 21 and 23 are to be broken off to form a separate fragment, fragment 13 is broken along fragmentation line 16A to break bridges 56. Sections 19, 21 and 23 forming the smaller fragment will still be linked together by bridges 54. Since bridges 54 will be intact, supplying power to any negative terminal 42 on fragment 23 and any positive terminal 40 on fragment 19 will cause all the LED in the smaller fragment to light up.

Apertures 48 are dimensioned and configured to receive a mounting screw (not shown) to permit the fragment to be easily mounted to a suitable housing by attaching the fragment to the housing via a plurality of mounting screws. Fragment 13 also has apertures 73 positioned between adjacent modules 18 and apertures 71 positioned at the center of each module. Apertures 73 and 71 are likewise dimensioned to receive a mounting screw. Apertures 48 are positioned along fragmentation lines 16 and 16A while apertures 73 are positioned along fragmentation lines 14. Hence apertures 48 and 73 act as both a mounting mechanism and also as part of the fragmentation lines.

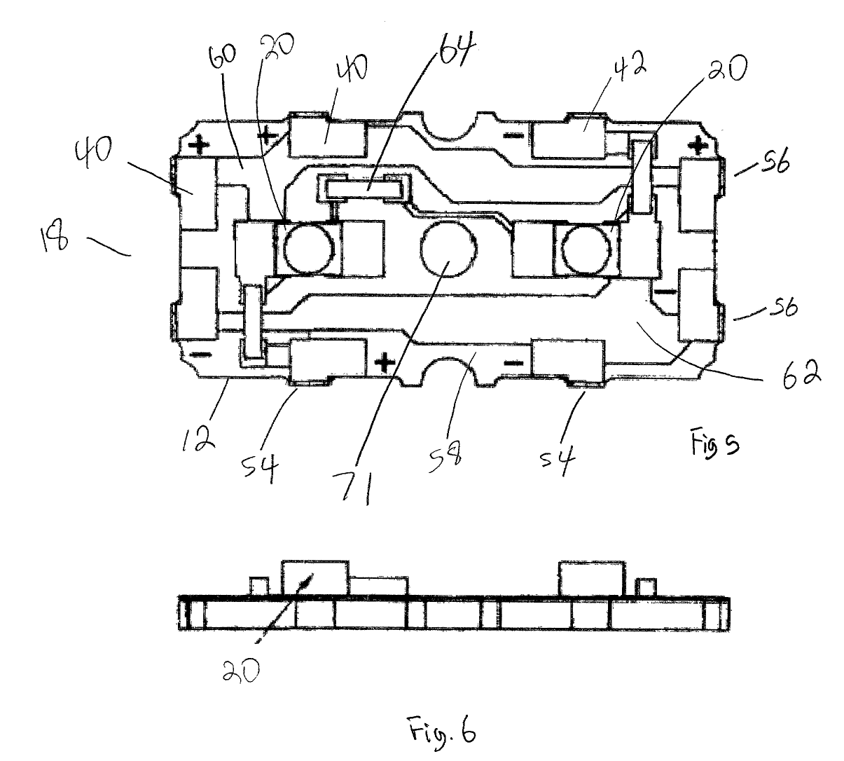

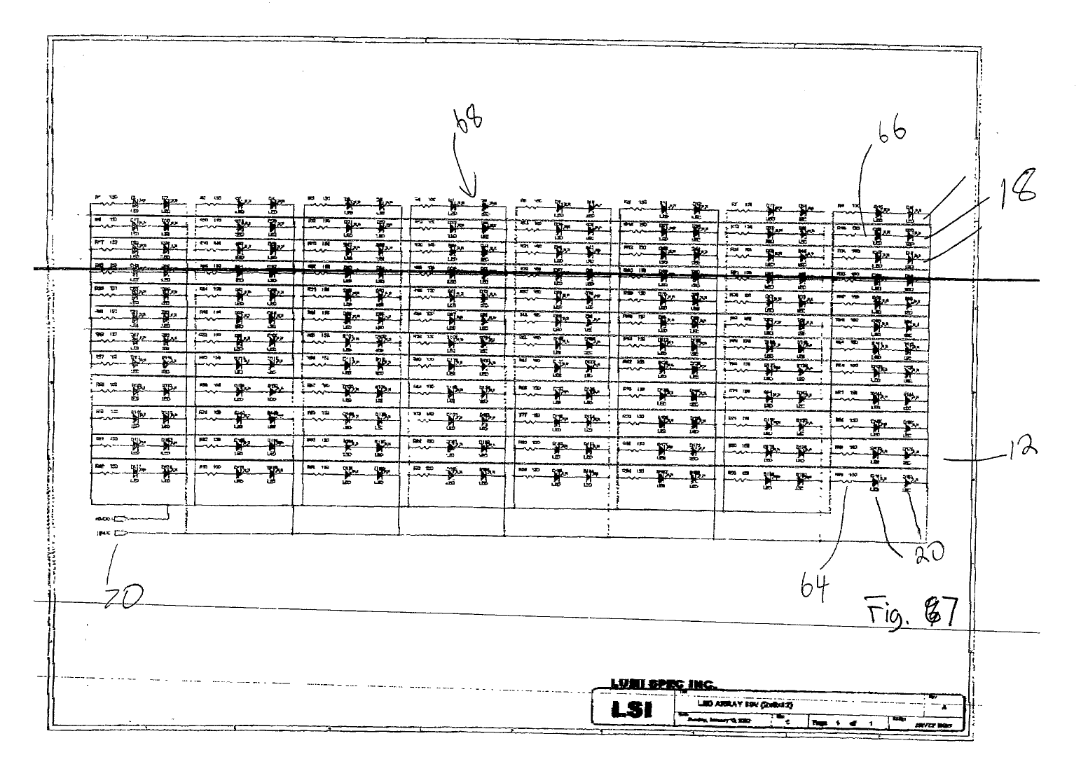

Referring now to FIGS. 5 and 6, each rectangular module 18 will have a sub-circuit 58 printed onto board material 12. Sub-circuit 58 will generally comprise conductors 60 and 62 which are part of a layer of conductive material embedded in board material 12 which was etched with a suitable circuit pattern. Conductor 60 is laid out such that it electrically couples all of the positive leads 40 together. Conductor 60 also connects to the positive sides of both LEDs 20. Likewise, conductor 62 is laid out such that it electrically couples all of the negative leads 42 together and the negative sides of both LEDs 20. Preferably, conductors 60 and 62 are made as thick as possible in order to act as a heat sink for LED's 20. A resistor element 64 may be incorporated into circuit 58 in order to limit the current flowing through LED's 20. A suitable resistor can be selected depending on the current and voltage rating of the LEDs 20 and the desired amount of luminous flux. Each module 18 will be provided with aperture 71, which is dimensioned and configure to receive a mounting screw or bolt. Aperture 71 ensures that each module 18 can be easily mounted to what ever housing is desired.

As mentioned previously, preferably, sections 18 are electrically coupled to each other in a parallel circuit such that supplying all the LEDs with current can be achieved by supplying current to any pair of positive and negative leads. A suitable circuit diagram is shown in FIG. 7. Each section 18 has a sub-circuit 66. Sub-circuits 66 of adjacent sections 18 are electrically coupled together in parallel to from a larger circuit 68. Larger circuit 68 may be supplied with electrical power via terminals 70. It will be appreciated that FIG. 7 represents a schematic representation of the entire circuit of LED's on board 12. Terminal 70 corresponds to terminals 40 and 42 of each module 18 (see FIG. 6).

Referring back to FIGS. 1 and 2, a user can start with LED circuit board 12 to form numerous circuit board fragments of useful size and shape. For example, if the user wishes to create an “L” shaped LED circuit board in order to manufacture a portion of an advertising display sign, the user can simply break board 12 along fragmentation lines 14 and 16 to create fragment 22 having the desired shape. Various sizes and shapes of circuit board fragments can be created simply by breaking the circuit board along the appropriate fragmentation lines. Each of the resulting fragments can be easily wired up to a suitable power source to form a functioning LED module. The current and voltage will depend on the number of LEDs on the fragment.

A specific embodiment of the present invention has been disclosed; however, several variations of the disclosed embodiment could be envisioned as within the scope of this invention. It is to be understood that the present invention is not limited to the embodiments described above, but encompasses any and all embodiments within the scope of the following claims.

Therefore, what is claimed is:

1. A modular LED circuit board comprising:
a) a circuit board being frangible along a first and second set of intersecting fragmentation lines, the fragmentation lines dividing the circuit board into a plurality of modules,
b) a plurality of LEDs mounted to the circuit board, at least one LED being mounted to each module.

2. A modular LED circuit board as defined in claim 1 wherein each module has a sub-circuit operatively coupled to the LED, each sub-circuit having a positive and negative terminal.

3. A modular LED circuit board as defined in claim 2 wherein the sub-circuits of adjacent modules are operatively coupled together by frangible leads.

4. A modular LED circuit board as defined in claim 3 wherein the sub-circuits are interlinked to form a common circuit having a common positive terminal and a common negative terminal, the common positive terminal consisting of any positive terminal of the sub-circuits and the common negative terminal consisting of any negative terminal of the sub-circuits.

5. A modular LED circuit board as defined in claim 3 wherein the sub-circuits are operatively coupled together in parallel.

6. A modular LED circuit board as defined in claim 1 wherein the first and second fragmentation lines are perpendicularly oriented to each other.

7. A modular LED circuit board as defined in claim 6 wherein the modules are substantially rectangular.

8. A modular LED circuit board as defined in claim 1 wherein the sub-circuits are operatively coupled to each other by frangible leads to form a larger circuit, the larger circuit coupling each LED on the circuit board to all of the positive leads and all of the negative leads.

9. A modular LED circuit board as defined in claim 1 wherein the circuit board is frangible along the fragmentation lines to form at least two board fragments, each board fragment having at least one module, the modules of each board fragment being operatively coupled to each other to form an LED circuit.

10. A modular LED circuit board as defined in claim 1 wherein each module is provided with a mounting aperture.

11. A modular LED circuit board comprising:
a) a circuit board being frangible along a first and second set of intersecting fragmentation lines, the fragmentation lines dividing the circuit board into a plurality of modules,
b) a plurality of LEDs mounted to the circuit board, at least one LED being mounted to each module,
c) the LED's being operatively coupled together in a circuit, the circuit having a plurality of frangible leads passing between the modules.

12. A modular LED circuit board as defined in claim 11 wherein each module has a positive and negative terminal.

13. A modular LED circuit board as defined in claim 12 wherein each module has opposite sides and opposite ends, each module having four pairs of positive and negative terminals one pair of terminals positioned adjacent each side and end of the module.

14. A modular LED circuit board as defined in claim 11 wherein the frangible leads cross the fragmentation lines.

15. A modular LED circuit board as defined in claim 11 wherein each module has a mounting aperture.

16. A modular LED circuit board comprising a circuit board being frangible along a first and second set of intersecting fragmentation lines, the fragmentation lines dividing the circuit board into a plurality of four sided modules, at least one LED being mounted to each module, the LED's being operatively coupled together in a circuit, the circuit having a plurality of frangible leads crossing the fragmentation lines between the modules, each module having at least one positive and one negative terminal.

17. A modular LED circuit board as defined in claim 16 wherein each module has a mounting aperture.

18. A modular LED circuit board as defined in claim 16 wherein each module has a pair of negative and positive terminals positioned adjacent each of its sides.

19. A modular LED circuit board as defined in claim 17 wherein each module has two LED's, one LED on either side of the mounting aperture.

20. A modular LED circuit board as defined in claim 16 wherein the circuit is a parallel electrical circuit.

21. A modular LED circuit board as defined in claim 11 wherein the circuit board has a plurality of mounting apertures positioned along at least one set of fragmentation lines.

22. A modular LED circuit board as defined in claim 21 wherein the circuit board has two series of mounting apertures, each set of apertures positioned along a set of fragmentation lines.
